(19) United States
(12) Patent Application Publication
(10) Pub. No.: US 2016/0013228 A1
(43) Pub. Date: Jan. 14, 2016

(54) SOLID-STATE IMAGING DEVICE AND METHOD FOR MANUFACTURING SOLID-STATE IMAGING DEVICE

(71) Applicant: Kabushiki Kaisha Toshiba, Minato-ku (JP)

(72) Inventor: Hironobu FUKUI, Oita (JP)

(73) Assignee: Kabushiki Kaisha Toshiba, Minato-ku (JP)

(21) Appl. No.: 14/717,149

(22) Filed: May 20, 2015

(30) Foreign Application Priority Data
Jul. 10, 2014 (JP) 2014-142618

(51) Int. Cl. H01L 27/146

(52) U.S. Cl. CPC H01L 27/14614; H01L 27/14612; H01L 27/14643; H01L 27/14689; H01L 27/1461; H01L 27/1463; H01L 27/14698

(57) ABSTRACT

According to one embodiment, a solid-state imaging device includes a semiconductor layer, a charge transfer region, a floating diffusion (FD), and a reading gate. The semiconductor layer is provided with a photoelectric conversion element. The charge transfer region is formed on a surface of the semiconductor layer over a charge accumulation region in the photoelectric conversion element. The FD is provided on the charge transfer region to hold a charge transferred from the charge accumulation region. The reading gate is provided on a side surface of the FD and a side surface of the charge transfer region via an insulating film.

### CROSS-REFERENCE TO RELATED APPLICATIONS

This application is based upon and claims the benefit of priority from Japanese Patent Application No. 2014-142618, filed on Jul. 10, 2014; the entire contents of which are incorporated herein by reference.

### FIELD

Embodiments described herein relate generally to a solid-state imaging device and a method for manufacturing the solid-state imaging device.

### BACKGROUND

Conventionally, there has been a solid-state imaging device in which a photoelectric conversion element and a floating diffusion are disposed in a plane direction of a semiconductor layer at intervals, and a reading gate is provided on a surface of the semiconductor layer interposed by the photoelectric conversion element and the floating diffusion via a gate insulating film.

In such a solid-state imaging device, when a predetermined voltage is applied to the reading gate, a channel is formed on a surface layer of the semiconductor layer below the reading gate. Thus, in the solid-state imaging device, a signal charge subjected to the photoelectric conversion by the photoelectric conversion element is transferred to the floating diffusion through the channel.

However, in the recent solid-state imaging devices, an interval between the photoelectric conversion element and the floating diffusion is narrowed as the miniaturization of the pixel progresses, the gate length of the reading gate is shortened accordingly, and a potential barrier between the photoelectric conversion element and the channel tends to rise.

In the solid-state imaging device, when the potential barrier between the photoelectric conversion element and the channel rises, a signal charge to be transferred to the floating diffusion remains in the photoelectric conversion element without being transferred, and an afterimage may occur in the captured image.

### BRIEF DESCRIPTION OF THE DRAWINGS

FIG. 1 is a block diagram illustrating a schematic configuration of a digital camera equipped with a solid-state imaging device according to an embodiment;

FIG. 2 is a block diagram illustrating a schematic configuration of the solid-state imaging device according to the embodiment;

FIG. 3 is a perspective view illustrating a pixel array according to the embodiment;

FIG. 4 is a schematic plan view illustrating a part of an opposite side to a light-receiving surface of a pixel array from which a support substrate and a multilayer wiring layer illustrated in FIG. 3 are peeled off;

FIG. 5 is a schematic cross-sectional view taken along a line A-A′ of the pixel array illustrated in FIG. 4;

FIGS. 6A to 9C are explanatory views illustrating manufacturing processes of the solid-state imaging device according to the embodiment in cross-sectional views; and

FIGS. 10A and 10B are explanatory views illustrating a schematic cross section of the solid-state imaging device according to modified examples of the embodiment.

### DETAILED DESCRIPTION

According to an embodiment, a solid-state imaging device is provided. The solid-state imaging device includes a semiconductor layer, a charge transfer region, a floating diffusion and a reading gate. The semiconductor layer is provided with a photoelectric conversion element. The charge transfer region is formed on a surface of the semiconductor layer over a charge accumulation region in the photoelectric conversion element. The floating diffusion is provided on the charge transfer region to hold a charge transferred from the charge accumulation region via the charge transfer region. The reading gate is provided on a side surface of the floating diffusion and a side surface of the charge transfer region via a gate insulating film.

A solid-state imaging device and a method for manufacturing the solid-state imaging device according to the embodiment will be described in detail with reference to the accompanying drawings. In addition, the invention is not intended to be limited by the embodiment.

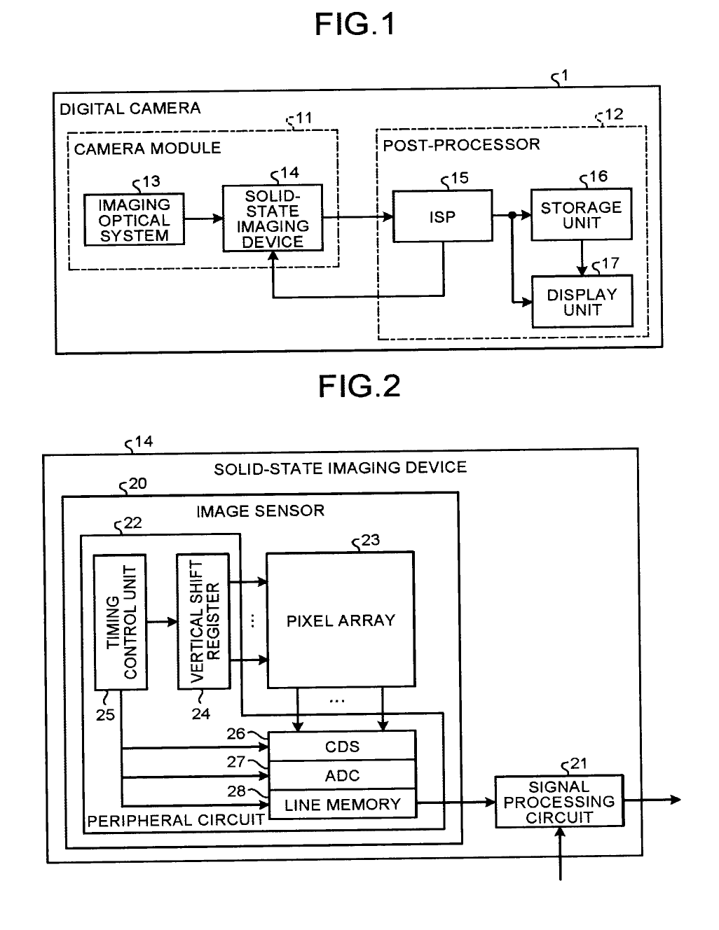

FIG. 1 is a block diagram illustrating a schematic configuration of a digital camera 1 equipped with a solid-state imaging device 14 according to the embodiment. As illustrated in FIG. 1, the digital camera 1 is equipped with a camera module 11 and a post-processor 12.

The camera module 11 is equipped with an imaging optical system 13 and the solid-state imaging device 14. The imaging optical system 13 captures light from an object to form an object image. The solid-state imaging device 14 captures the subject image formed by the imaging optical system 13, and outputs an image signal obtained by imaging to the post-processor 12. Such a camera module 11, for example, is also applied to an electronic apparatus such as a mobile terminal with a camera, in addition to the digital camera 1.

The post-processor 12 is equipped with an image signal processor (ISP) 15, a storage unit 16 and a display unit 17. The ISP 15 performs signal processing of an image signal which is input from the solid-state imaging device 14. The ISP 15, for example, performs high-quality image processing such as noise removal processing, defective pixel correction processing and resolution conversion processing.

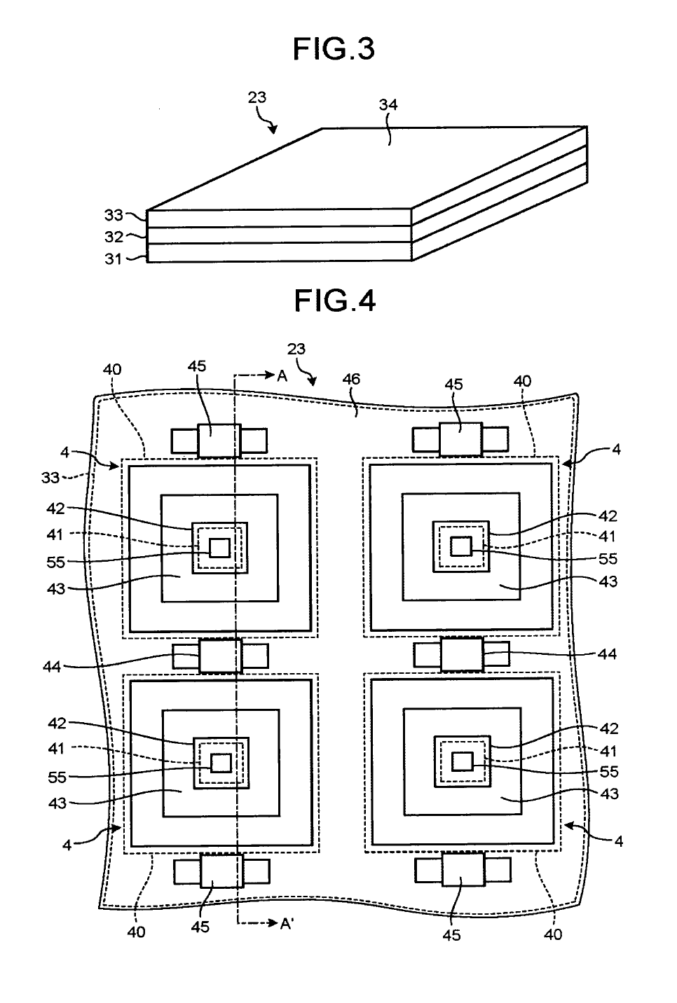

The ISP 15 outputs an image signal after the signal processing to the storage unit 16, the display unit 17 and a signal processing circuit 21 (see FIG. 2) to be described later equipped in the solid-state imaging device 14 in the camera module 11. The image signal fed back from the ISP 15 to the camera module 11 is used for adjustment and control of the solid-state imaging device 14.

The storage unit 16 stores the image signal input from the ISP 15 as an image. The storage unit 16 outputs an image signal of the stored image to the display unit 17 depending on the operation of a user or the like. The display unit 17 displays an image depending on the image signal that is input from the ISP 15 or the storage unit 16. Such a display unit 17, for example, is a liquid crystal display.

Next, the solid-state imaging device 14 equipped in the camera module 11 will be described with reference to FIG. 2. FIG. 2 is a block diagram illustrating a schematic configuration of the solid-state imaging device 14 according to the embodiment. As illustrated in FIG. 2, the solid-state imaging device 14 is equipped with an image sensor 20 and a signal processing circuit 21.

Here, the description will be given of a case where the image sensor 20 is a so-called backside irradiation type complementary metal oxide semiconductor (CMOS) image sensor in which a wiring layer is formed on a surface side opposite to a surface to which incident light of the photoelectric conversion element configured to photoelectrically convert the incident light is incident. In addition, the image sensor 20 according to this embodiment may be a surface irradiation type CMOS image sensor, without being limited to the backside irradiation type CMOS image sensor.

The image sensor 20 is equipped with a peripheral circuit 22 configured at the center of an analog circuit, and a pixel array 23. The peripheral circuit 22 is equipped with a vertical shift register 24, a timing control unit 25, a correlated double sampling unit (CDS) 26, an analog-digital converter (ADC) 27 and a line memory 28.

The pixel array 23 is provided in an imaging region of the image sensor 20. In such a pixel array 23, a plurality of photoelectric conversion elements corresponding to each pixel of the captured image is disposed in a horizontal direction (row direction) and a vertical (column direction) in a two-dimensional array shape (matrix shape). Moreover, in the pixel array 23, the photoelectric conversion elements corresponding to each pixel generate and accumulate a signal charge (for example, electrons) corresponding to the quantity of incident light.

When a predetermined voltage is applied to the reading gate provided for each photoelectric conversion element, the signal charges accumulated in the photoelectric conversion elements are transferred to the floating diffusion through the charge transfer region and held.

In the pixel array 23 of this embodiment, the photoelectric conversion element, the charge transfer region and the floating diffusion are stacked in a thickness direction of the semiconductor layer in which the plurality of photoelectric conversion elements is provided in the two-dimensional array shape. Moreover, in the pixel array 23, the reading gates are provided on the side surface of the floating diffusion and the side surface of the charge transfer region via the gate insulating film.

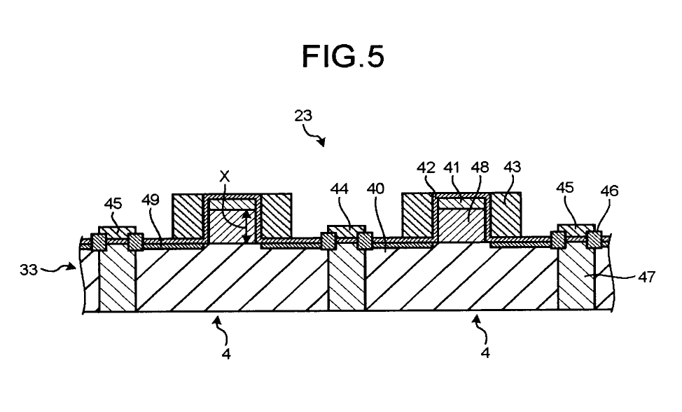

Thus, the pixel array 23 can secure the reading gate having the sufficient gate length in the thickness direction of the semiconductor layer, without being influenced by the miniaturization of pixels. Therefore, according to the pixel array 23, by preventing an increase in potential barrier between the photoelectric conversion element and the channel accompanying the miniaturization of pixels, it is possible to suppress an occurrence of afterimage in the captured image. A specific example of the configuration of the pixel array 23 will be described below with reference to FIGS. 3 to 5.

The timing control unit 25 is a processor that outputs a pulse signal as a reference of the operation timing to the vertical shift register 24. Also, the timing control unit 25 is also connected to the CDS 26, the ADC 27 and the line memory 28, and also performs the timing control of the operation of the CDS 26, the ADC 27 and the line memory 28.

The vertical shift register 24 is a processor which outputs a selection signal for sequentially selecting the photoelectric conversion elements, which read the signal charge from the plurality of photoelectric conversion elements two-dimensionally disposed in an array (matrix) shape, by the row unit, to the pixel array 23.

The pixel array 23 outputs the signal charge accumulated in each photoelectric conversion element selected by the row unit by the selection signal input from the vertical shift register 24, from the photoelectric conversion element as a pixel signal indicating luminance of each pixel to the CDS 26.

The CDS 26 is a processor which removes the noise from the pixel signal input from the pixel array 23 by the correlated double sampling and outputs the pixel signal to the ADC 27. The ADC 27 is a processor that converts an analog pixel signal input from the CDS 26 into a digital pixel signal, and outputs the digital pixel signal to the line memory 28. The line memory 28 is a processor that temporarily holds the pixel signal input from the ADC 27, and outputs the pixel signal to the signal processing circuit 21 for each row of the photoelectric conversion element in the pixel array 23.

The signal processing circuit 21 is a processor which is configured at the center of the digital circuit, performs predetermined signal processing on the pixel signal input from the line memory 28, and outputs the pixel signal after the signal processing as an image signal to the post-processor 12. The signal processing circuit 21 performs the signal processing such as lens shading correction, defect correction and noise reduction processing, on the pixel signal.

Thus, in the image sensor 20, a plurality of photoelectric conversion elements disposed in the pixel array 23 photoelectrically converts and accumulates the incident light into the quantity of signal charges depending on the quantity of received light, and the peripheral circuit 22 performs imaging by reading the signal charge accumulated in each photoelectric conversion element as a pixel signal.

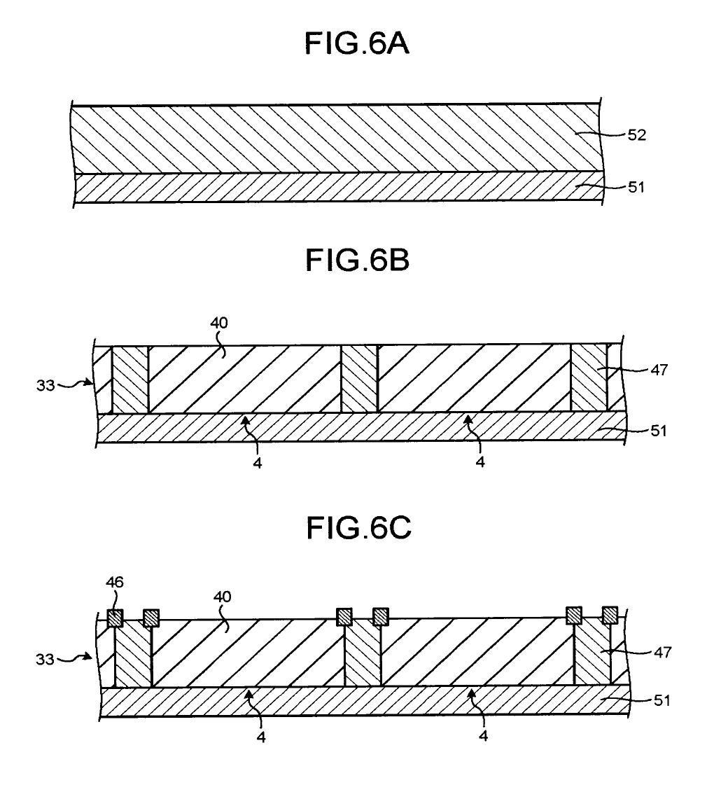

Next, the configuration of the pixel array 23 according to the embodiment will be described with reference to FIGS. 3 to 5. FIG. 3 is a perspective view illustrating the pixel array 23 according to the embodiment. Also, FIG. 4 is a schematic plan view illustrating a part of a surface (hereinafter, referred to as a “lower surface”) opposite to the light-receiving surface 34 of the pixel array 23 from which the support substrate 31 and the multilayer wiring layer 32 illustrated in FIG. 3 are peeled off.

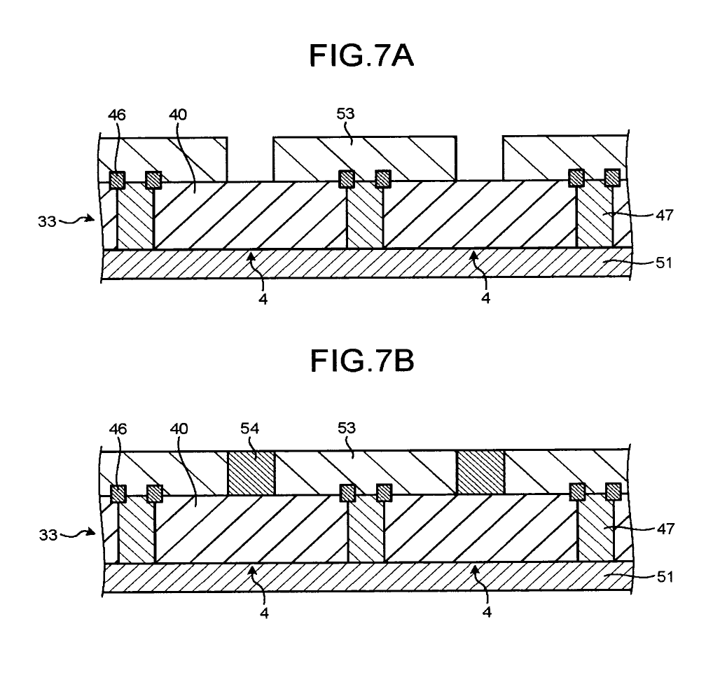

Also, FIG. 5 is a schematic cross-sectional view taken from a line A-A′ of the pixel array 23 illustrated in FIG. 4. FIG. 5 illustrates a cross-section of the structure of a state in which the light-receiving surface 34 faces downward, and does not illustrate the color filter and the micro lens provided in the light-receiving surface 34.

As illustrated in FIG. 3, the pixel array 23 includes the support substrate 31, the multilayer wiring layer 32 provided on the support substrate 31, and a semiconductor layer 33 provided on the multilayer wiring layer 32. The support substrate 31 is a substrate which is stuck so as to provide the thin semiconductor layer 33 in the manufacturing process of the solid-state imaging device described below.

Moreover, the multilayer wiring layer 32 is a layer in which a multilayer wiring is provided inside the interlayer insulating film. The multilayer wiring is a wiring that connects each of the semiconductor elements provided in the semiconductor layer 33, and the above-mentioned peripheral circuit 22 (see FIG. 2) or the like.

As illustrated in FIG. 4, the semiconductor layer 33 is provided with a plurality of photoelectric conversion elements 4 in a two-dimensional array shape. Each photoelectric conversion element 4 includes a charge accumulation region 40 which photoelectrically converts the light incident from the light-receiving surface 34 into the signal charges and accumulates the signal charges. At the center of the lower surface of each charge accumulation region 40, a floating diffusion 41 is provided via a charge transfer region 48 to be described below (see FIG. 5).

In addition, on the side surface of the floating diffusion 41 and the side surface of the charge transfer region 48, an annular reading gate 43 which surrounds the floating diffusion 41 and the charge transfer region 48 is provided via a gate insulating film 42.

Thus, in the pixel array 23, as compared to a case where the charge accumulation region 40, the reading gate 43 and the floating diffusion 41 of the photoelectric conversion element 4 are provided side by side in the plane direction of the semiconductor layer 33, a free space between the adjacent photoelectric conversion elements 4 is widened.

Therefore, in the pixel array 23, a reset gate 44 and an amplifier gate 45 are provided on the surface (here, a lower surface) of the semiconductor layer 33 between the adjacent photoelectric conversion elements 4. The reset gate 44 is a gate of a reset transistor which resets the charge which is present in the floating diffusion 41 before imaging.

Also, the amplifier gate 45 is a gate of the amplifier transistor which amplifies the signal charge held in the floating diffusion 41. An element isolation insulating film 46 is provided on the lower surface of the semiconductor layer 33 among the reading gate 43, the reset gate 44, and the amplifier gate 45. In addition, at the center of the lower surface of the floating diffusion 41, a contact plug 55 connected to the source of the reset transistor and the amplifier gate 45 is provided.

Moreover, the cross section of the structure illustrated in FIG. 4 is illustrated in FIG. 5. Specifically, the pixel array 23, for example, includes a plurality of photoelectric conversion elements 4 which is formed by a PN junction between an element isolation region 47, in which P-type impurities are ion-implanted into the semiconductor layer 33 formed of silicon, and a charge accumulation region 40 in which N-type impurities are ion-implanted.

Further, the pixel array 23 includes a charge transfer region (channel region) 48 formed on the surface (the upper surface in the drawings) of the semiconductor layer 33 over the charge accumulation region 40 in the photoelectric conversion element 4. The charge transfer region 48, for example, is provided at a central position on the surface (the upper surface in the drawings) opposite to the light-receiving surface 34 (the lower surface in the drawings) in the charge accumulation region 40 of the photoelectric conversion element 4. Furthermore, the pixel array 23 includes the floating diffusion 41 on the charge transfer region 48.

Then, in the pixel array 23, the reading gates 43 are provided on the side surface of the floating diffusion 41 and the side surface of the charge transfer region 48 via the gate insulating film 42. Such reading gates 43, for example, are formed of polysilicon in an annular shape that surrounds the floating diffusion 41 and the charge transfer region 48. In addition, in a surface layer portion on the side of the charge accumulation region 40 in which the charge transfer region 48 is provided, a P-type diffusion layer 49 in which the P-type impurities are diffused is provided.

In addition, the gate insulating film 42, for example, is formed of silicon oxide, and is also provided on a surface other than the region in which the charge transfer region 48 is provided on the surface (here, the upper surface) opposite to the light-receiving surface 34 of the semiconductor layer 33, and on the surface of the floating diffusion 41.

In the cross section illustrated in FIG. 5, the surface of the floating diffusion 41 is covered with the gate insulating film 42, but a part of the gate insulating film 42 on the front side of this portion is selectively removed. Moreover, a contact plug 55 illustrated in FIG. 4 is provided on the surface of the floating diffusion 41 of the portion in which the gate insulating film 42 is removed. Further, the reset gate 44 and the amplifier gate 45, for example, are formed of polysilicon on the surface of the element isolation region 47 via the gate insulating film 42.

In such a pixel array 23, when a predetermined voltage is applied to the reading gate 43, a channel is formed at an interface between the charge transfer region 48 and the gate insulating film 42. Thus, the signal charge subjected to the photoelectrical conversion by the photoelectric conversion element 4 is transferred from the charge accumulation region 40 to the floating diffusion 41 through the channel and is held.

Thus, in the pixel array 23, a distance X from the interface between the charge transfer region 48 and the charge accumulation region 40 to the interface between the charge transfer region 48 and the floating diffusion 41 becomes a gate length of the reading gate 43.

Thus, the pixel array 23 can secure the reading gate 43 having a sufficient gate length in the thickness direction of the semiconductor layer 33, that is, in a direction parallel to the normal line of the light-receiving surface 34, without being influenced by the miniaturization of pixels.

Therefore, according to the pixel array 23, it is possible to suppress an occurrence of afterimage in the captured image, by preventing a situation in which the gate length of the reading gate 43 is shortened with the miniaturization of pixels, and the potential barrier between the photoelectric conversion element and the channel rises.

Moreover, in the pixel array 23, the side surface of the floating diffusion 41 and the side surface of the charge transfer region 48 are entirely covered by the gate insulating film 42, and the reading gate 43 is provided on the entire surface of the gate insulating film 42. That is, the reading gate 43 is formed in an annular shape which surrounds the floating diffusion 41 and the charge transfer region 48 via the gate insulating film 42.

Accordingly, in the pixel array 23, when a predetermined voltage is applied to the reading gate 43, a channel is formed on the entire side circumferential surface of the charge transfer region 48. Thus, the pixel array 23 can efficiently transfer the signal charge from the charge accumulation region 40 to the floating diffusion 41.

Furthermore, in the pixel array 23, the charge transfer region 48 is provided on the surface of the semiconductor layer 33 over the charge accumulation region 40 rather than within the semiconductor layer 33, and the floating diffusion 41 is provided on the upper surface of the charge transfer region 48.

Thus, in the pixel array 23, since it is possible to use the entire inner region of the semiconductor layer 33 as a space for the photoelectric conversion element 4, it is possible to expand the light-receiving area of the photoelectric conversion element 4 and to increase the number of saturated electrons.

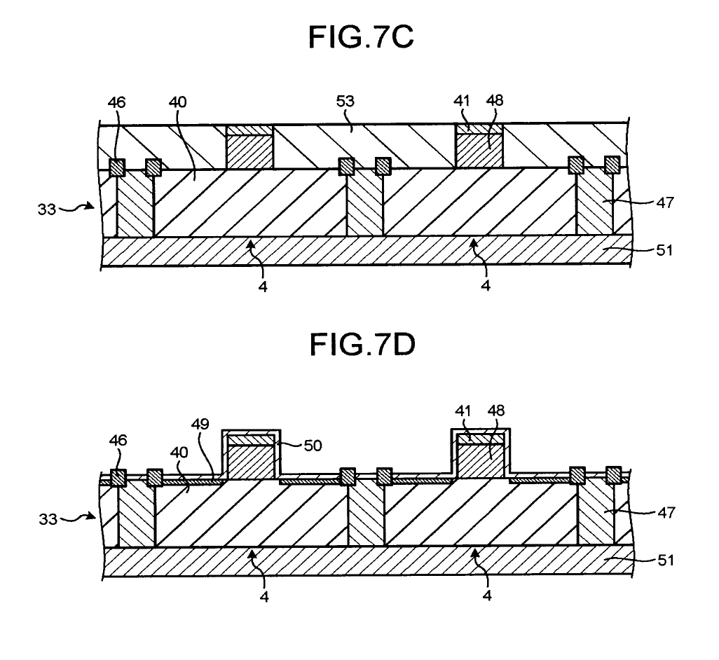

Next, a method for manufacturing the solid-state imaging device 14 according to the embodiment will be described with reference to FIGS. 6A to 9C. FIGS. 6A to 9C are explanatory views illustrating the manufacturing processes of the solid-state imaging device 14 according to the embodiment in a cross-sectional view. Here, the manufacturing processes of the pixel array 23 portion provided in the solid-state imaging device 14 will be described.

When manufacturing the pixel array 23, as illustrated in FIG. 6A, for example, an epitaxial layer 52 of silicon is formed on the upper surface of the semiconductor substrate 51 such as a silicon wafer, by chemical vapor deposition (CVD).

Next, for example, the N-type impurities such as phosphorus are ion-implanted into the epitaxial layer 52 in a matrix shape when viewed in a plan view, and the P-type impurities such as boron are ion-implanted between the regions in which the N-type impurities are ion-implanted, in a matrix shape when viewed in a plan view, so as to surround the regions in which the N-type impurities are ion-implanted.

Thereafter, by performing the annealing process, as illustrated in FIG. 6B, the charge accumulation region 40 in which the N-type impurities are thermally diffused, and the element isolation region 47 in which the P-type impurities are thermally diffused are formed. Thus, the semiconductor layer 33 is formed, in which a plurality of photoelectric conversion elements 4 formed by the PN junction between the P type element isolation region 47 and the N type charge accumulation region 40 are disposed in a two-dimensional array shape.

Thereafter, as illustrated in FIG. 6C, at a position where each photoelectric conversion element 4 and other semiconductor elements such as a reset transistor and an amplifier transistor to be formed later are isolated from each other, the element isolation insulating film 46 is formed, for example, by tetraethoxysilane (TEOS).

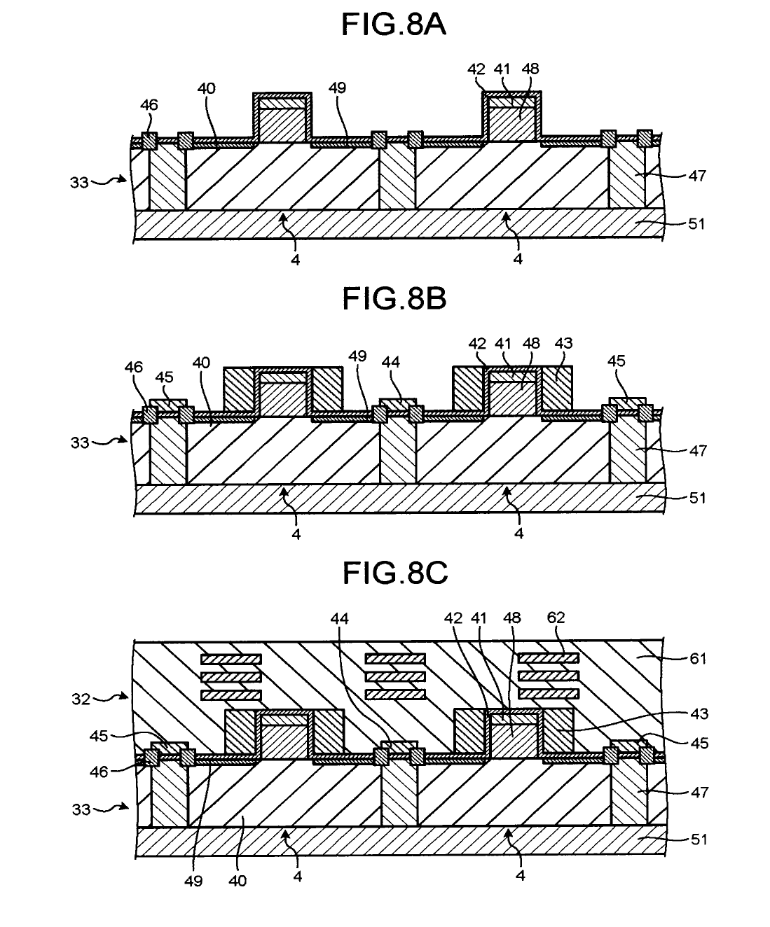

Next, as illustrated in FIG. 7A, for example, a mask material 53 such as silicon nitride is deposited on the surface of the semiconductor layer 33, and then, the mask material 53 on the surface center of the charge accumulation region 40 is selectively removed. Thus, an opening is formed in the mask material 53, and the surface central portion of the charge accumulation region 40 is exposed.

Next, as illustrated in FIG. 7B, the epitaxial region 54 is formed in the opening formed in the mask material 53, by selectively performing the epitaxial growth of silicon. Thereafter, the surface of the epitaxial region 54 is flattened, for example, by chemical mechanical polishing (CMP).

Next, as illustrated in FIG. 7C, after the P-type or N-type impurities are ion-implanted to the epitaxial layer 52, by performing the annealing process, the charge transfer region 48 is formed in which the P-type or N-type impurities are thermally diffused.

Thereafter, for example, after the N-type impurities such as phosphorus are ion-implanted to the surface layer portion of the charge transfer region 48, by performing the annealing process, the floating diffusion 41 is formed in which the N-type impurities are thermally diffused.

Next, after peeling off the mask material 53, a thermal oxidation process is performed. As a result, as illustrated in FIG. 7D, the protective film 50 of the oxide film is formed on the surface of the semiconductor layer 33 except for the portion provided with the charge transfer region 48, the side surface (the side circumferential surface) of the charge transfer region 48, and the side surface (the side circumferential surface) and the surface of the floating diffusion 41.

Thereafter, by forming a resist film (not illustrated) on the surface of the protective film 50, and by patterning the resist film by photolithography, a resist film is selectively left on the formation region of the amplifier transistor, the reset transistor, the peripheral logic circuit or the like.

Moreover, the resist film is used as a mask, and the P-type impurities such as boron are ion-implanted to the semiconductor layer 33 to perform the annealing process. Thus, a P-type diffusion layer 49 is formed on the surface layer on the side of the charge accumulation region 40 in which the charge transfer region 48 is provided.

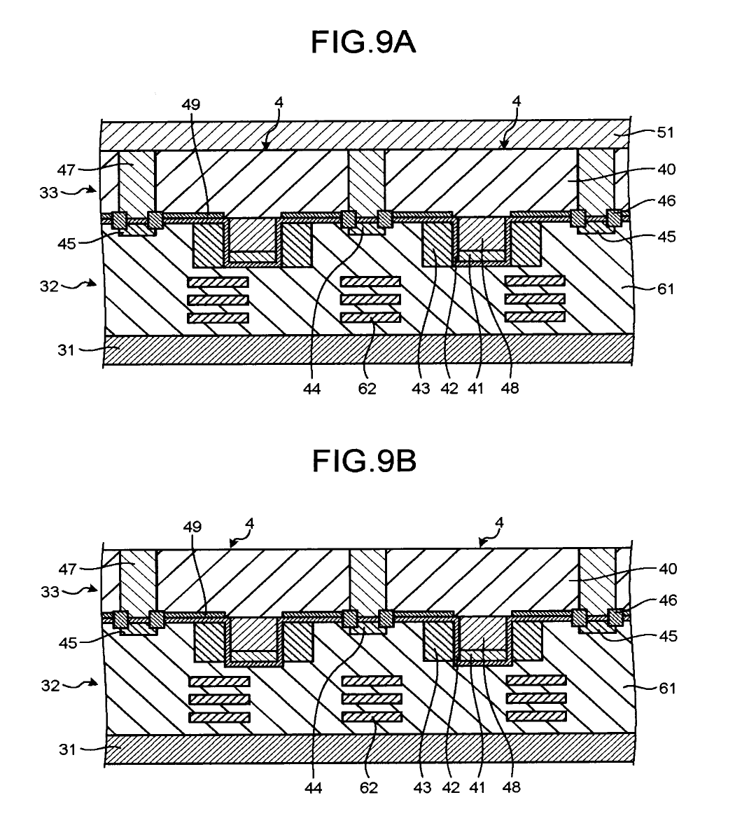

Thereafter, the thermal oxidation process is performed after removing the resist film and the protective film 50. As a result, as illustrated in FIG. 8A, the gate insulating film 42 is formed on the surface of the semiconductor layer 33 except for the portion provided with the charge transfer region 48, the side surface (the side circumferential surface) of the charge transfer region 48, and the side surface (the side circumferential surface) and the surface of the floating diffusion 41.

Thereafter, as illustrated in FIG. 8B, a reading gate 43 is formed, for example, by polysilicon so as to surround the side surface of the floating diffusion 41 and the side surface of the charge transfer region 48 via the gate insulating film 42. In the process of forming the reading gate 43, the reset gate 44 and the amplifier gate 45 are also formed simultaneously, for example, by polysilicon.

Thereafter, for example, the N-type impurities such as phosphorus are ion-implanted to both sides (a front side and a back side in the example illustrated in FIG. 8B) of the element isolation region 47 with the reset gate 44 interposed therebetween. In this process, at the same time, for example, the N-type impurities such as phosphorus are also ion-implanted to both sides (a front side and a back side in the example illustrated in FIG. 8B) of the element isolation region 47 with the amplifier gate 45 interposed therebetween.

Thereafter, by performing the annealing process, the N-type impurities are thermally diffused. Thus, the source and drain of the reset transistor are formed, and at the same time, the source and drain of the amplifier transistor are formed.

Next, as illustrated in FIG. 8C, the multilayer wiring layer 32 is formed on the surface side of the semiconductor layer 33. Here, the multilayer wiring layer 32 is formed, for example, by repeating a process of forming an interlayer insulating film 61, a process of patterning wiring grooves in the interlayer insulating film 61, and a process of forming a wiring 62 by embedding copper to the patterned grooves using a damascene method.

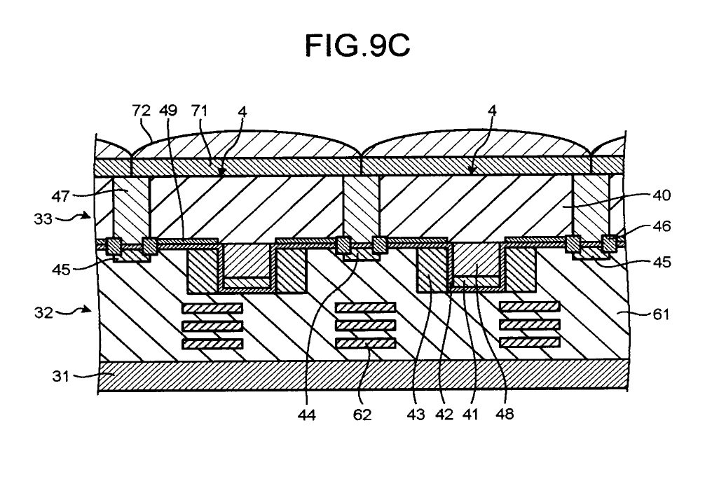

Thereafter, the support substrate 31 is stuck onto the multilayer wiring layer 32, and as illustrated in FIG. 9A, the structure, in which the semiconductor substrate 51, the semiconductor layer 33 and the support substrate 31 are stacked, is inverted upside down. Moreover, by grinding and polishing the semiconductor substrate 51 from the back surface (here, the upper surface) side, as illustrated in FIG. 9B, the back surface (here, the upper surface) of the semiconductor layer 33 is exposed.

Finally, as illustrated in FIG. 9C, by sequentially forming a color filter 71 and a micro lens 72 on the surface of the exposed semiconductor layer 33, the pixel array 23 is completed. Although the manufacturing processes of the solid-state imaging device 14 equipped with the backside irradiation type CMOS image sensor has been described in this embodiment, it is also possible to manufacture a solid-state imaging device equipped with a surface irradiation type CMOS image sensor, only by partially changing the above-mentioned manufacturing processes.

Specifically, in the process of forming the multilayer wiring layer 32 illustrated in FIG. 8C, the wiring 62 is provided at a position other than the photoelectric conversion element 4, and the color filter 71 and the micro lens 72 are formed on the multilayer wiring layer 32. This makes it possible to manufacture a solid-state imaging device equipped with a surface irradiation type CMOS image sensor.

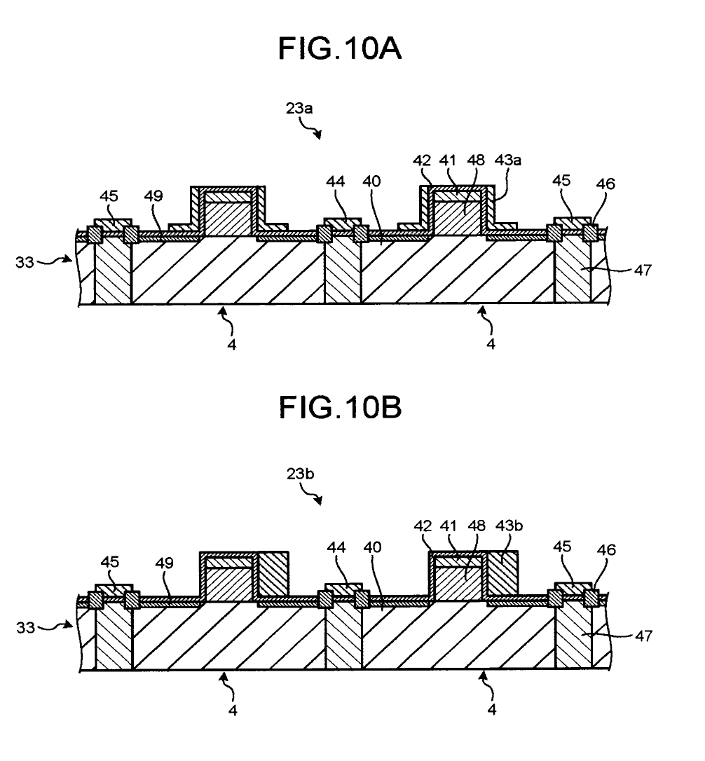

Further, the configuration of the pixel array 23 illustrated in FIG. 5 is an example, and various modifications can be made. Here, pixel arrays 23a and 23b according to a modified example of this embodiment will be described with reference to FIGS. 10A and 10B. FIGS. 10A and 10B are explanatory views illustrating a schematic cross section of a solid-state imaging device according to the modified example of the embodiment.

In addition, FIG. 10A illustrates a pixel array 23a of a solid-state imaging device according to a first modified example, and FIG. 10B illustrates a pixel array 23b of a solid-state imaging device according to a second modified example. Here, among the components illustrated in FIGS. 10A and 10B, the same components as illustrated in FIG. 5 are denoted by the same reference numerals as illustrated in FIG. 5, and the descriptions thereof will not be provided.

As illustrated in FIG. 10A, the pixel array 23a may be configured to include a reading gate 43a that is thinner than the reading gate 43 of the pixel array 23 illustrated in FIG. 5. In such a case, the reading gate 43a is formed in a L-shape when viewed in a cross-sectional view that continues along the side surface of the floating diffusion 41, the side surface of the charge transfer region 48, and the surface on the side of the charge accumulation region 40 in which the charge transfer region 48 is provided.

According to such a pixel array 23a, by forming the thin reading gate 43a, in addition to the effects achieved by the pixel array 23 illustrated in FIG. 5, it is possible to reduce the material used for forming the reading gate 43a and to shorten the time required for forming the reading gate 43a.

In addition, as illustrated in FIG. 10B, the pixel array 23b may be configured to have the reading gate 43b provided via the gate insulating film 42, on the side circumferential surface of a part of the entire side circumferential surfaces of the floating diffusion 41 and the charge transfer region 48.

It is also possible to provide the reading gate 43b having a sufficient gate length in the thickness direction of the semiconductor layer 33 by such a pixel array 23b, without being influenced by the miniaturization of pixel size, and it is also possible to reduce the material used for forming the reading gate 43b.

As described above, the solid-state imaging device according to the embodiment includes a semiconductor layer provided with the photoelectric conversion element, and a charge transfer region formed on the surface of the semiconductor layer over the charge accumulation region in the photoelectric conversion element.

Furthermore, the solid-state imaging device according to the embodiment includes a floating diffusion on the charge transfer region, and a reading gate that is provided on the side circumferential surfaces of the floating diffusion and the charge transfer region via the gate insulating film.

Thus, in the solid-state imaging device according to the embodiment, since it is possible to provide a reading gate having a sufficient gate length in the thickness direction of the semiconductor layer, without being influenced by the miniaturization of the pixel size, it is possible to suppress an occurrence of afterimage in the captured image due to the reduction of the gate length.

Moreover, in the solid-state imaging device according to the embodiment, it is possible to use the entire region in the semiconductor layer as a formation area of the photoelectric conversion element. Therefore, according to the solid-state imaging device of the embodiment, it is possible to increase the light-receiving area of the photoelectric conversion element and the number of saturated electrons, as compared to other solid-state imaging devices that are not equipped with the charge transfer region, the floating diffusion and the reading gate of the structure described in this embodiment.

Furthermore, the solid-state imaging device according to the embodiment is equipped with a gate of a reset transistor and an amplifier gate of an amplifier transistor, on the surface of the semiconductor layer between the adjacent photoelectric conversion elements. Thus, the solid-state imaging device according to the embodiment is capable of further reducing the pixel size, by providing the gate of the reset transistor and the gate of the amplifier transistor by effectively utilizing the free space between the adjacent photoelectric conversion elements.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid-state imaging device, comprising:
a semiconductor layer provided with a photoelectric conversion element;
a charge transfer region formed on a surface of the semiconductor layer over a charge accumulation region in the photoelectric conversion element;
a floating diffusion disposed on the charge transfer region and configured to hold a charge transferred from the charge accumulation region via the charge transfer region; and
a reading gate provided on a side surface of the floating diffusion and a side surface of the charge transfer region via a gate insulating film.

2. The solid-state imaging device according to claim 1, wherein
the reading gate is formed in an annular shape which surrounds the floating diffusion and the charge transfer region.

3. The solid-state imaging device according to claim 1, wherein
the reading gate is provided continuously along the side surface of the floating diffusion, the side surface of the charge transfer region, and a surface on a side of the charge accumulation region in which the charge transfer region is provided.

4. The solid-state imaging device according to claim 3, wherein
the reading gate has an L-shape when viewed in a cross section.

5. The solid-state imaging device according to claim 1, wherein
a plurality of photoelectric conversion elements is provided in the semiconductor layer in a two-dimensional array shape, and
a gate of an amplifier transistor configured to amplify the charge held in the floating diffusion, and a gate of a reset transistor configured to reset the charge held in the floating diffusion are provided on the surface of the semiconductor layer between the adjacent photoelectric conversion elements via a gate insulating film.

6. The solid-state imaging device according to claim 5, wherein
the gate of the amplifier transistor and the gate of the reset transistor are provided on the same layer on the semiconductor layer.

7. The solid-state imaging device according to claim 5, wherein
the semiconductor layer includes an element isolation region between the adjacent photoelectric conversion elements, and
the gate of the amplifier transistor and the gate of the reset transistor are provided on a surface of the element isolation region via the gate insulating film.

8. The solid-state imaging device according to claim 1, wherein
the reading gate is provided on a side circumferential surface of a part of the entire side circumferential surfaces of the floating diffusion and the charge transfer region.

9. A method for manufacturing a solid-state imaging device, comprising:
forming a photoelectric conversion element on a semiconductor layer;
forming a charge transfer region on a surface of the semiconductor layer over a charge accumulation region in the photoelectric conversion element;
forming a floating diffusion configured to hold a charge, which is transferred from the charge accumulation region via the charge transfer region, on the charge transfer region; and
forming a reading gate on a side surface of the floating diffusion and a side surface of the charge transfer region via a gate insulating film.

10. The method for manufacturing a solid-state imaging device according to claim 9, further comprising:
depositing a mask material on the surface of the semiconductor layer formed with the photoelectric conversion element;
forming an opening in the mask material by selectively removing the mask material on a surface center of the charge accumulation region;
forming an epitaxial region in the opening; and
forming the charge transfer region by ion-implanting P-type or N-type impurities to the epitaxial region to perform an annealing process.

11. The method for manufacturing a solid-state imaging device according to claim 10, further comprising:
forming the floating diffusion, by ion-implanting the N type impurities to a surface layer of the charge accumulation region to perform the annealing process.

12. The method for manufacturing a solid-state imaging device according to claim 11, further comprising
forming the gate insulating film, by oxidizing a surface of the semiconductor layer except for a portion provided with the charge transfer region, a side surface of the charge transfer region, and a side surface and a surface of the floating diffusion.

13. The method for manufacturing a solid-state imaging device according to claim 9, further comprising
forming the reading gate having an annular shape which surrounds the floating diffusion and the charge transfer region.

14. The method for manufacturing a solid-state imaging device according to claim 9, further comprising
forming the reading gate which continues along the side surface of the floating diffusion, the side surface of the charge transfer region, and a surface on a side of the charge accumulation region in which the charge transfer region is provided.

15. The method for manufacturing a solid-state imaging device according to claim 14, further comprising
forming the reading gate having an L-shape when viewed in a cross section.

16. The method for manufacturing a solid-state imaging device according to claim 9, further comprising:
forming a plurality of photoelectric conversion elements on the semiconductor layer in a two-dimensional array shape; and
forming a gate of an amplifier transistor configured to amplify the charge held in the floating diffusion, and a gate of a reset transistor configured to reset the charge held in the floating diffusion, on the surface of the semiconductor layer between the adjacent photoelectric conversion elements, via a gate insulating film.

17. The method for manufacturing a solid-state imaging device according to claim 16, further comprising
forming the reading gate, the gate of the amplifier transistor, and the gate of the reset transistor at the same time.

18. The method for manufacturing a solid-state imaging device according to claim 16, further comprising:
forming an element isolation region between the adjacent photoelectric conversion elements in the semiconductor layer; and
forming the gate of the amplifier transistor and the gate of the reset transistor on a surface of the element isolation region via a gate insulating film.

19. The method for manufacturing a solid-state imaging device according to claim 9, further comprising
forming the reading gate on a side circumferential surface of a part of the entire side circumferential surfaces of the floating diffusion and the charge transfer region, via the gate insulating film.
